(19) United States
(12) Patent Application Publication
(10) Pub. No.: US 2019/0285930 A1
(43) Pub. Date: Sep. 19, 2019

(54) GATE DRIVER ON ARRAY (GOA) UNIT, GOA CIRCUIT, AND LIQUID CRYSTAL DISPLAY (LCD) PANEL

(71) Applicant: SHENZHEN CHINA STAR OPTOELECTRONICS SEMICONDUCTOR DISPLAY TECHNOLOGY CO., LTD., Shenzhen (CN)

(72) Inventors: Ren-Lu CHEN, Shenzhen (CN); Mian ZENG, Shenzhen (CN)

(21) Appl. No.: 16/101,300

(22) Filed: Aug. 10, 2018

Related U.S. Application Data
(63) Continuation of application No. PCT/CN2018/079825, filed on Mar. 21, 2018.

(30) Foreign Application Priority Data
Mar. 13, 2018 (CN) 201810203482.9

(51) Int. Cl. G02F 1/1345; G09G 3/36

(52) U.S. Cl. CPC G02F 1/13454; G09G 3/3677; G11C 19/28; G09G 2300/0408; G09G 2310/08

(57) ABSTRACT

The present disclosure relates to a gate driver on array (GOA) unit. An output end of the pull-up controlling module, a control end of the pull-up circuit, a first end of the pull-down maintaining circuit, a first end of the pull-down circuit, a control end of the signal down-transfer circuit, and a first end of the bootstrap module connect to a gate signal point. A second end of the pull-down maintaining circuit, a second end of the pull-down circuit, a second end of the bootstrap module, and an output end of the pull-up circuit connect to a horizontal scanning line. A third end of the pull-down maintaining circuit and a third end of the pull-down circuit connect to a first level signal line. A fourth end of the pull-down maintaining circuit and a fourth end of the pull-down circuit connect to a second level signal line.

### CROSS REFERENCE TO RELATED APPLICATIONS

This application is a continuing application of PCT Patent Application No. PCT/CN2018/079825, entitled “ARRAY SUBSTRATE AND MANUFACTURING METHOD THEREOF”, filed on Mar. 21, 2018, which claims priority to Chinese Patent Application No. 201810203482.9, filed on Mar. 13, 2018, both of which are hereby incorporated in its entireties by reference.

### BACKGROUND

### 1. Technical Field

The present disclosure relates to an electronic field, more particularly to a gate driver on array (GOA) unit, a GOA circuit, and a liquid crystal display (LCD) panel.

### 2. Description of Related Art

The gate driver on array (GOA) is a technique that manufacturing a gate scanning-driving circuit of a thin film transistor (TFT) onto an array substrate to replace a driving chip manufactured by an external silicon wafer. The GOA circuit may directly be manufactured on the rim of the panel, such that the thickness of the frame of the liquid crystal display (LCD) panel may be reduced, the manufacturing process may be simplified, the cost may be reduced, and the integrality may be improved.

The conventional GOA circuit may include a plurality of GOA unit connected in cascade. Each of the GOA units may include a pull-up controlling module, a pull-up circuit, a down-transfer circuit, a pull-down circuit, a pull-down maintaining circuit, and a bootstrap capacitor configured to lift a potential. The pull-up maintaining circuit is configured to control the pull-up circuit to turn on. The pull-up maintaining circuit is configured to receive down-transfer signals from a GOA unit at a previous level or gate signals. The pull-up circuit is configured to transform clock signals (CK) into the gate signals. The pull-down circuit is configured to rapidly pull-down scanning-driving signals, i.e., a potential of the gate of the TFT, to a low level, so as to turn off the gate signals. The pull-down maintaining circuit is configured to maintain the scanning-driving signals and the gate signals of the pull-up circuit (Q point) to be at a turn-off state (That is, a negative potential element). Usually, the two pull-down maintaining circuits operate in an alternative manner. The bootstrap capacitor is configured to secondary lift the potential of the “Q” point.

The actual output of the GOA circuit is configured to determine the performance of the GOA circuit. The gate signal waveform may include a low potential phase, a first high potential phase, and a second high potential phase. In the second high potential phase, a rising time of the gate signal waveform is the time length that the potential is lifted to the potential of the second high potential phase, and a falling time is the time length that the potential is pulled-down from the potential of the second high potential phase to the potential of the low potential phase. However, if the rising time and the falling time of the gate signal waveform are not short enough, and the time length that the potential is maintained to be at the high level of the second high potential phase may be shortened. The charging efficiency of the horizontal scanning line, especially in the gate driver of the Tri-Gate structure, may be affected due to the short charging time.

### SUMMARY

The present disclosure relates to a gate driver on array (GOA) unit, a GOA circuit, and a liquid crystal display (LCD) capable of reducing a rising time and a falling time of gate signals, so as to improve charging performance.

In one aspect, the present disclosure relates to the GOA unit, including: a pull-up controlling module, a pull-up circuit, a pull-down maintaining circuit, a pull-down circuit, a signal down-transfer circuit, and a bootstrap module; an output end of the pull-up controlling module, a control end of the pull-up circuit, a first end of the pull-down maintaining circuit, a first end of the pull-down circuit, a control end of the signal down-transfer circuit, and a first end of the bootstrap module connect to a gate signal point, a second end of the pull-down maintaining circuit, a second end of the pull-down circuit, a second end of the bootstrap module, and an output end of the pull-up circuit connect to a horizontal scanning line G(N), a third end of the pull-down maintaining circuit and a third end of the pull-down circuit connect to a first level signal line, a fourth end of the pull-down maintaining circuit and a fourth end of the pull-down circuit connect to a second level signal line, an input end of the pull-up circuit and the input end of the signal down-transfer circuit connect to a clock signal line, a control end of the pull-down circuit connects to a GOA unit at a next level; a potential of the first level signal line is lower than a potential of the second level signal line; the pull-up controlling module is configured to pre-charge the gate signal point, the bootstrap module is configured to store and maintain a level of the gate signal point, when the gate signal point is at a turn-on level, the pull-up circuit is configured to output signals of the clock signal line to the horizontal scanning line; when control signals received by the control end of the pull-down circuit is configured to be at the turn-on level, the pull-down circuit is configured to output signals of the second level signal line to the horizontal scanning line and to output signals of the first level signal line to the gate signal point, the signals of the first level signal line are configured to control the second end of the pull-down maintaining circuit to output the signals of the second level line to the horizontal scanning line.

In another aspect, the present disclosure further relates to the GOA circuit, including: a plurality of GOA units, as described in above, connected in cascade, wherein a GOA unit at a N-th level is configured to control a horizontal scanning line at the N-th level to conduct a charging process; the control end of the signal down-transfer circuit in the GOA unit at the N-th level connects to the GOA unit at the next level, wherein “N” is a positive integral,

In another aspect, the present disclosure further relates to the LCD panel, including the GOA circuit described in above.

In view of the above, two potentials are provided by the first level signal line and the second level signal line. The potential of the first level signal line is lower than the potential of the second level signal line. The potential of second level signal line is configured to maintain the potential of the horizontal scanning line to be at a low level bit. The pull-down circuit and the pull-down maintaining circuit may be controlled by increasing the potential of the first level signal line, so as to reduce the rising time and the falling time in the gate signal waveform. As such, the potential maintained at the high level of the second high potential phase may be increased, the charging time may be increased, and the charging performance may be improved.

### BRIEF DESCRIPTION OF THE DRAWINGS

FIG. 1 is a schematic view of a gate on driver (GOA) unit in accordance with one embodiment of the present disclosure.

FIG. 2 is a diagram illustrating signals of a GOA unit in accordance with one embodiment of the present disclosure.

FIG. 3 is a schematic view of a GOA unit in accordance with another embodiment of the present disclosure.

FIG. 4 is a schematic view of a GOA unit in accordance with another embodiment of the present disclosure.

FIG. 5 is a schematic view of a GOA unit in accordance with another embodiment of the present disclosure.

FIG. 6 is a schematic view of a GOA unit in accordance with another embodiment of the present disclosure.

FIG. 7 is a gate signal waveform simulation diagram of a GOA unit in accordance with another embodiment of the present disclosure.

FIG. 8 is a schematic view of a GOA circuit in accordance with another embodiment of the present disclosure.

### DETAILED DESCRIPTION

To clarify the purpose, technical solutions, and the advantages of the disclosure, embodiments of the invention will now be described more fully hereinafter with reference to the accompanying drawings, in which embodiments of the invention are shown. The figure and the embodiment described according to figure are only for illustration, and the present disclosure is not limited to these embodiments. References herein to “embodiment” indicate that a particular feature, structure, or characteristic be included in at least one embodiment of the present disclosure. The appearances of phrases in various places in the specification are not necessarily all referring to the same embodiment, nor are separate or alternative embodiments mutually exclusive of other embodiments. Those skilled in the art will directly and implicitly understand that the embodiments described herein can be combined with other embodiments.

All other embodiments obtained by a person of ordinary skill in the art based on the embodiments of the present disclosure without creative efforts shall fall within the protection scope of the present disclosure.

It should be noted that the relational terms herein, such as “first” and “second”, are used only for differentiating one entity or operation, from another entity or operation, which, however do not necessarily require or imply that there should be any real relationship or sequence. Moreover, the terms “comprise”, “include” or any other variations thereof are meant to cover non-exclusive including, so that the process, method, article or device comprising a series of elements do not only comprise those elements, but also comprise other elements that are not explicitly listed or also comprise the inherent elements of the process, method, article or device. In the case that there are no more restrictions, an element qualified by the statement “comprises a . . . ” does not exclude the presence of additional identical elements in the process, method, article or device that comprises the said element.

It is also to be understood that the terminology used in the description of the present disclosure herein is for the purpose of describing particular embodiments only and is not intended to be limiting the disclosure. As used in the description of the disclosure and the claims, the singular forms “a”, “an”, and “the” are intended to include the plural forms as well, unless the context clearly indicates otherwise.

It should also be further understood that the term “and/or” used in the description of the disclosure and the claims refers to any combination of one or more of the associated listed items and all possible combinations, and includes such combinations.

In this specification and the claims, the term “if” may be interpreted depending on the context as “when” or “once” or “in response to a determination” or “in response to detection”. Similarly, the phrase “if determined” or “if the [condition or event described] is detected” may be interpreted in accordance with the context to mean “once determining”, “in response to a determination”, “once determining the [condition or event described]”, or “in response to the determination of a [condition or event described].”

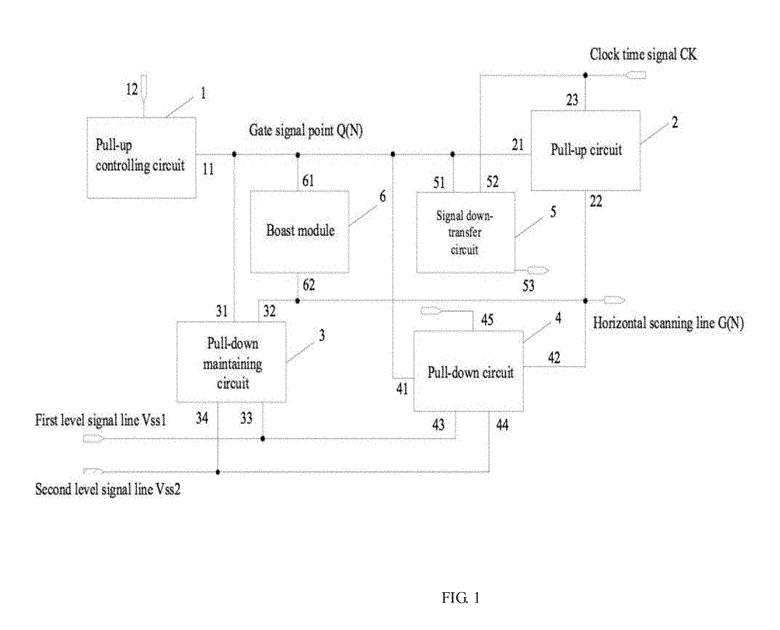

Referring to FIG. 1, the present disclosure relates to a gate driver on array (GOA) unit, including: a pull-up controlling module 1, a pull-up circuit 2, a pull-down maintaining circuit 3, a pull-down circuit 4, a signal down-transfer circuit 5, and a bootstrap module 6.

An output end 11 of the pull-up controlling module 1, a control end 21 of the pull-up circuit 2, a first end 31 of the pull-down maintaining circuit 3, a first end 41 of the pull-down circuit 4, a control end 51 of the signal down-transfer circuit 5, and a first end 61 of the bootstrap module 6 connect to a gate signal point Q(N). A second end 32 of the pull-down maintaining circuit 3, a second end 42 of the pull-down circuit 4, a second end 62 of the bootstrap module 6, and an output end 22 of the pull-up circuit 2 connect to a horizontal scanning line G(N). A third end 33 of the pull-down maintaining circuit 3 and a third end 43 of the pull-down circuit 4 connect to a first level signal line Vss1. A fourth end 34 of the pull-down maintaining circuit 3 and a fourth end 44 of the pull-down circuit 4 connect to a second level signal line Vss2. An input end 23 of the pull-up circuit 2 and the input end 52 of the signal down-transfer circuit 5 connect to a clock signal line CK. A control end 45 of the pull-down circuit 4 connects to a GOA unit at a next level.

A potential of the first level signal line Vss1 is lower than a potential of the second level signal line Vss2.

The pull-up controlling module 1 is configured to pre-charge the gate signal point Q(N). The bootstrap module 6 is configured to store and maintain a potential of the gate signal point Q(N). When the gate signal point Q(N) is at a turn-on level, the pull-up circuit 2 is configured to output signals of the clock signal line CK to the horizontal scanning line G(N). When control signals received by the control end 45 of the pull-down circuit 4 is configured to be at the turn-on level, the pull-down circuit 4 is configured to output signals of the second level signal line Vss2 to the horizontal scanning line G(N) and to output signals of the first level signal line Vss1 to the gate signal point Q(N). The signals of the first level signal line Vss1 are configured to control the second end 32 of the pull-down maintaining circuit 3 to output the signals of the second level line Vss2 to the horizontal scanning line G(N).

The pull-up controlling module 1 may receive pull-up controlling signals configured to control the pull-up controlling module 1 to turn on and turn off. The pull-up controlling module 1 may receive signals of the horizontal scanning line of the GOA unit at a previous level or a constant direct current (DC) voltage. The pull-up controlling module 1 is configured to pre-charge the gate signal point Q(N). The pull-up circuit 2 is configured to lift a potential of the horizontal scanning line G(N). The bootstrap module 6 is configure to lift and maintain a potential of the gate signal point Q(N). The pull-down maintaining circuit 3 is configured to maintain the potential of the gate signal point Q(N) to he the same with the potential of the first level signal line Vss1 and to maintain the potential of the horizontal scanning line G(N) to be the same with the potential of the second level line Vss2. The pull-down circuit 4 is configured to pull-down the potential of the gate signal point Q(N) to the potential of the first level signal line Vss1, and to pull-down the potential of the horizontal scanning line G(N) to the potential of the second level signal line Vss2. The signal down-transfer circuit 5 is configured to control the GOA unit at the next level to turn on or turn off, wherein the GOA unit at the next level connects to the GOA unit.

The GOA unit at the previous level described in above indicates the GOA unit at the previous level connected to the GOA unit at a current level. The GOA unit at the previous level may not be adjacent to the GOA unit at the current level. That is, at least one GOA unit may be physically arranged between the GOA unit at the current level and the GOA unit at the previous level. The GOA unit at the next level indicates the GOA unit at the next level connected to the GOA unit at the current level. The GOA unit at the next level may not be adjacent to the GOA unit at the current level. That is, at least one GOA unit may be physically arranged between the GOA unit at the current level and the GOA unit at the next level. For example, in a structure of a GOA unit at a N-th level and a GOA unit at a (N+6)-th level, the GOA unit at the N-th level may respectively connect to the GOA unit at the previous level, i.e., a GOA unit at a (N−6)-th level, and the GOA unit at the next level, i.e., a GOA unit at the (N+6)-th level.

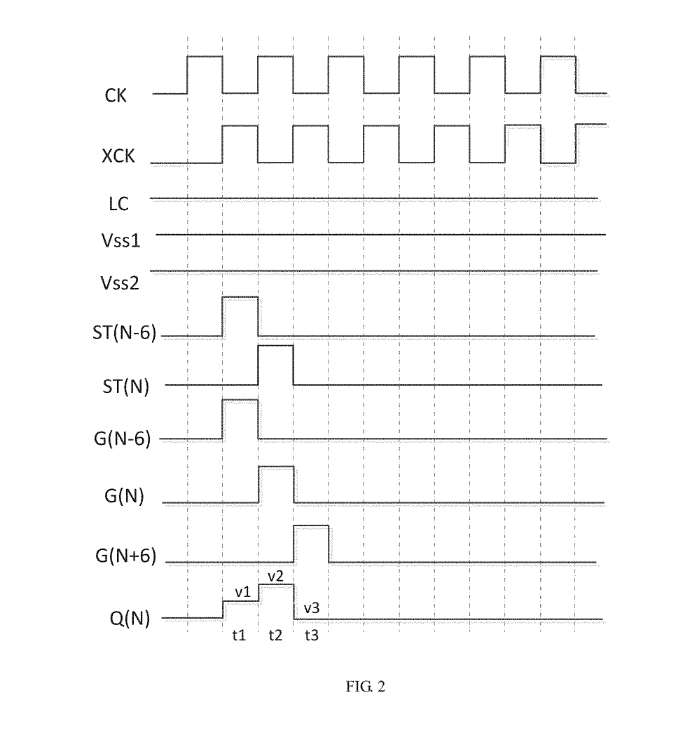

Taking the structure of the GOA unit at the N-th level and the GOA unit at the (N+6)-th level as an example. Signal charges are shown in FIG. 2. As shown in FIG. 2, signals XCK are reverse signals of the signals of the clock signal line CK. In a time period t1, the pull-up controlling module 1 may conduct a pre-charging process on the gate signal point Q(N) to achieve the turn-on level v1 capable of driving the pull-up circuit 2. The pull-up circuit 2 may he turned on, and the signals of the clock signal line CK may be transmitted to the horizontal scanning line G(N). As such, the horizontal scanning line G(N) is configured to be at a low level (substantially, the pull-up controlling signals ST(N−6) and the signals G(N−6) of the horizontal scanning line of the GOA unit at the previous level are originated from the signals of the clock signal line CK obtained from the GOA unit at the previous level in the time period t1), and the signals of the clock signal line CK are configured to pull-down the potential of the horizontal scanning line G(N). In a time period t2, the bootstrap module 6 is configured to pull-up the potential of the gate signal point Q(N) to v2. The pull-up circuit 2 is configured to transmit the signals of the clock signal line CK to the horizontal scanning line G(N). As such, the horizontal scanning line G(N) is configured to be at a high level, and the pull-up circuit 2 is configured to lift the potential of the horizontal scanning line G(N). In a time period t3, the potential of the gate signal point Q(N) is pulled-down to a low level v3 due to termination of a capacitive coupling effect of the signals LC of the pull-up maintaining circuit 3. The pull-up circuit 2 may keep transmitting the signals of the clock signal line CK to the horizontal scanning line G(N). As such, the horizontal scanning line G(N) is configured to be at the low level. The control signals Q(N+6) received by the control end 45 of the pull-down circuit 4 are configured to be at the high level. The pull-down circuit 4 may be turned on. The pull-down circuit 4 may transmit the signals of the first level signal line Vss1 to the gate signal point Q(N), and pull-down circuit 4 may transmit the signals of the second level signal line Vss2 to the horizontal scanning line G(N), wherein the signals of the clock signal line CK and the signals of the second level signal line Vss2 are configured to pull-down the potential of the horizontal scanning line G(N).

It can be seen that the signals of the first level signal line Vss1 are configured to pull-down the potential of the gate signal point Q(N), i.e., a voltage adopted by the pull-down maintaining circuit 3 and the pull-down circuit 4 when pulling-down the gate signal point Q(N). The signals of the second level signal line Vss2 are configured to pull-down the potential of the horizontal scanning line G(N), i.e., a voltage adopted by the pull-down maintaining circuit 3 and the pull-down circuit 4 when pulling-down the horizontal scanning line G(N).

The low level and the high level described in above respectively indicate a low voltage and a high voltage, which are relative levels. A voltage range of the low level may not overlap with a voltage range of the high level, and the voltage range of the low level is lower than the voltage range of the high level. For example, the voltage range of the low level is from 0V to 3V (include 0V and 3V), and the voltage range of the high level is from 3 to 6 V (include 6V, but not include 3V). In a digital logic circuit, the low level indicates “0”, and the high level indicates “1”.

The potential of the first level signal line Vss1 is lower than the potential of the second level signal line Vss2. Conventionally, only one level signal line is adopted. Adding another level signal line, having the potential lower than the previous level signal line, configured to be as the low level of the gate signal point Q(N) may shorten a rising time and a falling time of potential of the gate signal point Q(N) in a third phase. That is, the potential may be lifted rapidly to a potential of the third potential phase, and the potential may be dropped rapidly to the potential of the first level signal line Vss1 when being pulled-down. As such, a time length that the gate signal point Q(N) is maintained to be at the potential of the third phase becomes longer, and an effective charging time may be extended.

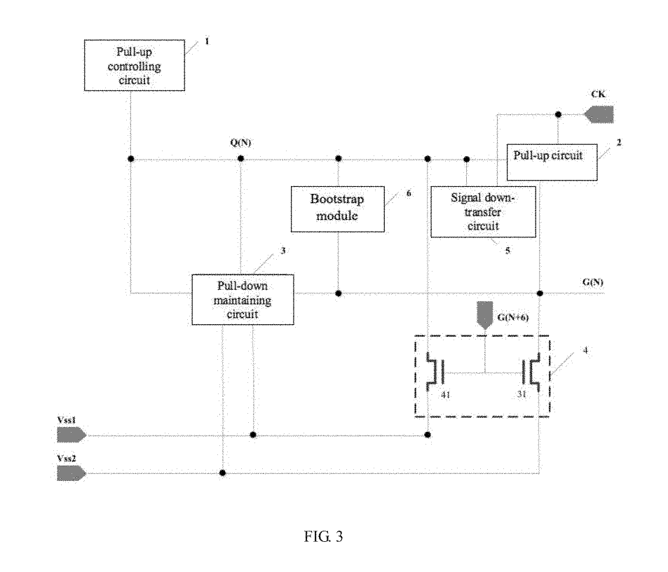

Referring to FIG. 3, FIG. 3 is a schematic view of a GOA unit in accordance with another embodiment of the present disclosure. Based on the embodiment shown in FIG. 1, the pull-down circuit 400 may include a first transistor 41 and a second transistor 31.

A drain of the first transistor 41 connects to the gate signal point Q(N). A drain of the second transistor 31 connects to the horizontal scanning line G(N). A source of the first transistor 41 connects to the first level signal line Vss1. A source of the second transistor 31 connects to the second level signals line Vss2.

When the gate of the first transistor 41 is at the turn-on level, the source of the first transistor 41 is configured to output the signals of the first level signal line Vss1 to the drain of the first transistor 41. When the gate of the second transistor 31 is at the turn-on level, the source of the second transistor 31 is configured to output the signals of the second level signal line Vss2 to the drain of the second transistor 31.

In one example, the turn-on level may be an input voltage configured to turn on electronic components, and may be an opening voltage (threshold voltage) of the transistors. That is, a gate voltage is configured to form a conductive channel between the source and the drain of the transistor. For example, when a gate of a transistor “A” is at a potential “a”, the transistor “A” is turned on, and the transistor “A” operates at a saturation state. The potential “a” is the turn-on level of the transistor “A”. In another example, the turn-on level may be of a range. In other words, when the potential of the gate of the transistor “A” is within the range, the transistor “A” may be turned on, and the transistor “A” operates at the saturation state.

The gate of the first transistor 41 and the gate of the second transistor 31 are configured to be control ends of the pull-down circuit. The control end of the pull-down circuit is configured to connect to the horizontal scanning line of the GOA unit at the next level. For example, the GOA unit at the (N+6)-th level. The potential of the horizontal scanning line G(N+6) is configured to control an operational state of the pull-down circuit. For example, the first transistor 41 and the second transistor 31 may be made of metal oxide semiconductor (MOS). The average turn-on level of a standard N-channel MOS transistor may be in a range from 3V to 6V. The average turn-on level may be in a range from 2V to 3V by improving the manufacturing process.

When the horizontal scanning line G(N+6) of the GOA unit at the (N+6)-th level is at the high level, i.e., the gate of the first transistor 41 and the gate of the second transistor 31 are at the turn-on level, and the first transistor 41 and the second transistor 31 may be turned on. The signals of the first level signal line Vss1 may he transmitted from the source of the first transistor 41 is to the drain of the first transistor 41, and the signals of the first level signal line Vss1 may be transmitted to the gate signal point Q(N). The signals of the second level signal line Vss2 may he transmitted from the source of the second transistor 31 to the drain of the second transistor 31, and the signals of the second level signal line Vss2 may be transmitted to the horizontal scanning line G(N).

In one example, a channel width of the first transistor in the GOA unit is less then 1000 micron.

The channel indicates a thin semiconductor layer configured between a source region and a drain region of a field effect transistor (FET). A current within the FET is controlled by a gate potential. The channel width is a width of the thin semiconductor layer from the source region to the drain region. The channel width is a significant sign of integral circuit (IC) integrity.

Specifically, the channel width of the first transistor may be 700 micron, 500 micron, and 650 micron.

In a circuit structure of the GOA unit of one level signal line, the channel width of the first transistor may be 1000 micron. The potential of the first level signal line Vss1 is lower than the potential of the second level signal line Vss2. When the channel width of the first transistor is less than 1000 micron, the potential of the gate signal point Q(N) may he pulled-down even faster in a second phase. As such, the rising time and the falling time of the potential of the gate signal point Q(N) may be shortened.

The potential of the first level signal line Vss1 is lower than the potential of the second level signal line Vss (equivalent to Vss2). Conventionally, only one level signal line is adopted. Adding another level signal line, having the potential lower than the previous level signal line, configured to be as the low level of the gate signal point Q(N) may shorten the rising time and the falling time of potential of the gate signal point Q(N) in the third phase. That is, the potential may be lifted rapidly to the potential of the third potential phase, and the potential may he dropped rapidly to the potential of the first level signal line Vss1 when being pulled-down. As such, the time length that the gate signal point Q(N) is maintained to be at the potential of the third phase becomes longer, and the effective charging time may be extended.

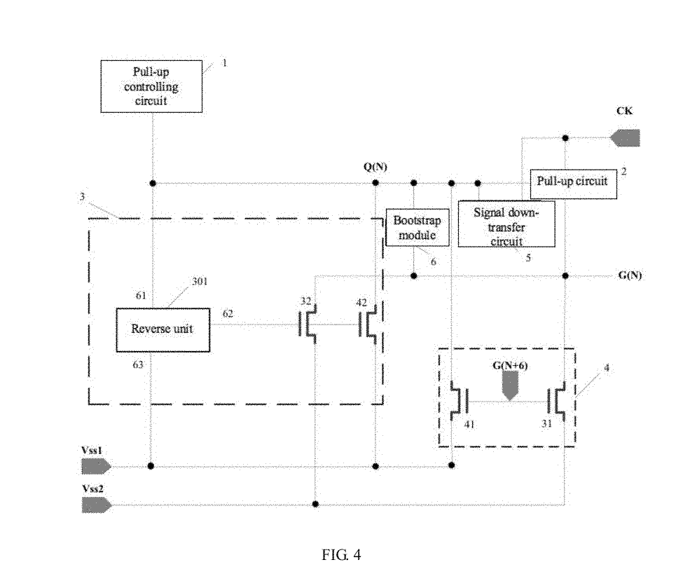

Referring to FIG. 4, FIG. 4 is a schematic view of a GOA unit in accordance with another embodiment of the preset disclosure. Based on the embodiment shown in FIG. 3, the pull-down maintaining circuit 3 may include a reverse unit 301, a fourth transistor 32, and a fifth transistor 42.

A control end 61 of the reverse unit 301 connects to the gate signal point Q(N). An output end 62 of the reverse unit 301 connects to a gate of the fourth transistor 32 and a gate of the fifth transistor 42.

A drain of the fourth transistor 32 connects to the horizontal scanning line G(N). A source of the fourth transistor 32 connects to the second level signal line Vss2. A drain of the fifth transistor 42 connects to the gate signal point Q(N). A source of the fifth transistor 42 connects to the first level signal line Vss1.

When the control end 61 of the reverse unit 301 is at a low level state, the output end 62 of the reverse unit 301 is configured to output at the turn-on level toward the gate of the fourth transistor 32 and the gate of the fifth transistor 42. In one example, the turn-on level may be a voltage configured to turn on the fourth transistor 32 and the fifth transistor 42, i.e., the turn-on level is configured to turn on the fourth transistor 32 and the fifth transistor 42. The signals of the second level signal line Vss2 are outputted from the source of the fourth transistor 32 to the drain of the fourth transistor 32, and the signals of the second level signal line Vss2 are outputted to the horizontal scanning line G(N). The signals of the first level signal line Vss1 are outputted from the source of the fifth transistor 42 to the drain of the fifth transistor 42, and signals of the first level signal line Vss1 are outputted to the gate signal point Q(N).

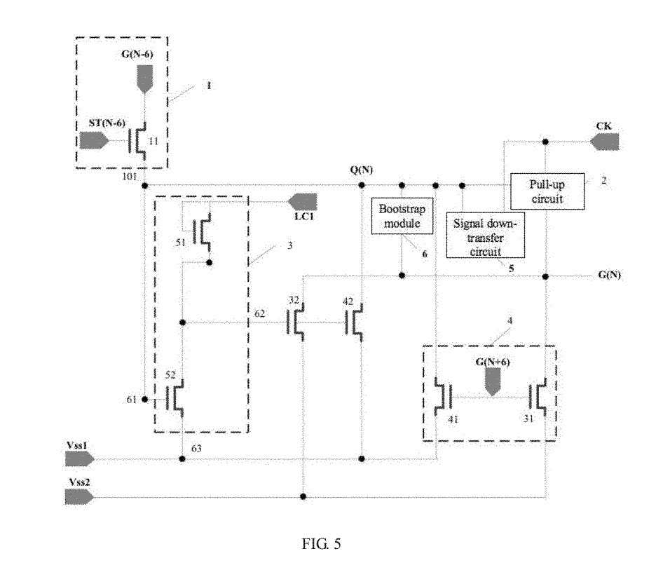

In one example, as shown in FIG. 5, the reverse unit 301 may include: a sixth transistor 51 and a seventh transistor 52.

A gate and a drain of the sixth transistor 51 connect to turn-on level signals LC1. A source of the sixth transistor 51 and a drain of the seventh transistor 52 connect to the output end of the reverse unit 301, and a gate of the seventh transistor 52 connects to an output end 101 of the pull-up controlling module 1.

The gate and the drain of the sixth transistor 51 connect to the turn-on level signals LC1, wherein the turn-on level signals LC1 are high potential signals wherein a potential of the turn-on level signals LC1 is higher than the potential of the first level signals line Vss1.

In one example, the reverse unit 301 may be an inverter. A potential of the input end 61 of the reverse unit 301 is opposite to a potential of the output end 62 of the reverse unit 301. When the input end 61 of the reverse unit 301 is at the low level state, the output end 62 of the reverse unit 301 may output at the high level. When the input end 61 of the reverse unit 301 is at a high level state, the output end 62 may output at the low level.

The pull-down maintaining circuit 3 is configured to maintain the potential of the horizontal scanning line G(N) when the potential of the horizontal scanning line G(N) is pulled-down to the potential of the first level signal line Vss1 by the pull-down circuit 4. The pull-down maintaining circuit 3 is configured to maintain the potential of the gate signal point Q(N) when the potential of the gate signal point Q(N) is pulled-down to the potential of the second level signal line Vss2 by the pull-down circuit 4.

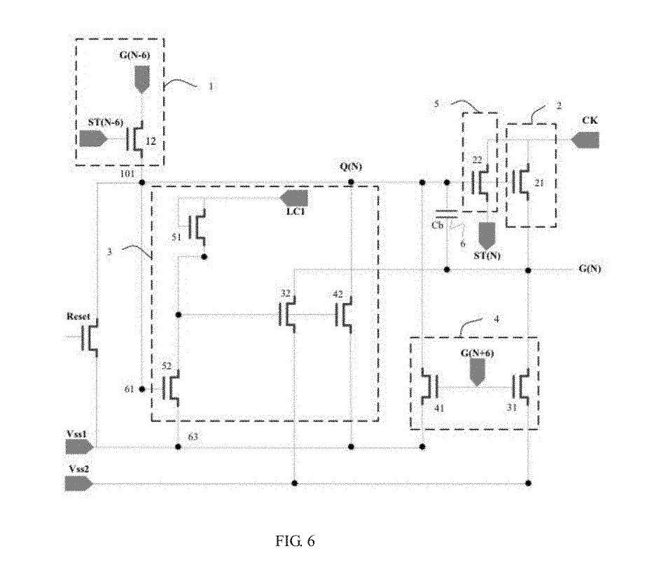

In one example, as shown in FIG. 6. Based on the embodiment shown in FIG. 5, the pull-up circuit 2 may include a third transistor 21.

A gate of the third transistor 21 is configured to connect to the gate signal point Q(N). A drain of the third transistor 21 is configured to connect to the clock signal line CK. A source of the third transistor 21 is configured to connect to the horizontal scanning line G(N). A channel width of the third transistor may be greater than 7000 micron.

When the gate of the third transistor 21 is at the turn-on level, the signals of the clock signal line CK may be outputted from the drain of the third transistor 21 to the source of the third transistor 21. That is, the signals of the clock signal line CK may be outputted to the horizontal scanning line G(N).

Specifically, the channel width of the third transistor may be 8200 micron, 9000 micron, and 10000 micron.

The potential of the horizontal scanning line G(N) may be pulled-up to be as high level signals of the clock signal line CK by the pull-up circuit 2. In the circuit structure of the GOA unit of one level signal line, the channel width of the third transistor may be 7000 micron. The potential of the first level signal line Vss 1 is lower than the potential of the second level signal line Vss2. When the channel width of the third transistor is greater than 7000 micron, the rising time and the falling time of the potential of the gate signal point Q(N) at the third phase may be shortened.

As shown in FIG. 6, the pull-up circuit 1 may include a transistor 12. A gate of the transistor 12 is a control end of the pull-up controlling module 1, and the gate of the transistor 12 is configured to receive the pull-up controlling signals, i.e., the signals ST(N−6) of the signal down-transfer circuit of the GOA unit at the previous level. The signal down-transfer circuit 5 may include a transistor 22. A gate of the transistor 22 is the control end of the signal down-transfer circuit 5, and the gate of the transistor 22 is configured to connect to the gate signal point Q(N). A drain of the transistor 22 is configured to connect to the clock signal line CK. A source of the transistor 22 is configured output the down-transfer controlling signals ST(N). The source of the transistor 22 is configured to connect the pull-up controlling module of the GOA unit at the next level, i.e., the source of the transistor 22 is configured to output the down-transfer signals ST(N) to the GOA unit at the (N+6)-th level.

In one example, the potential of the first level signal line Vss1 of the GOA unit is lower than the potential of the second level signal line Vss2 of the GOA unit in a range from 2 to 7 volt.

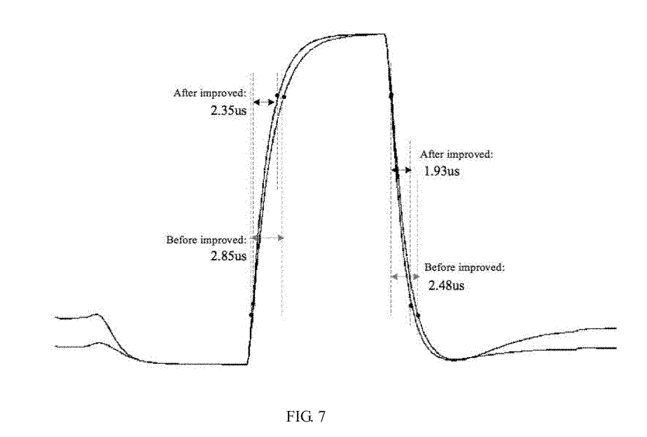

For example, a channel width of the third transistor may be 10000 micron. In another example, the channel width of the third transistor may be 500 micron. The potential of the first level signal line Vss1 may be 6.5 volt lower than the potential of the second level signal line Vss2. A gate signal waveform simulation diagram as shown in FIG. 7 may be obtained by a test. The rising time of the improved gate signal waveform is reduced by 0.5 us, and the falling time is reduced by 0.55 us. That is, the rising time and the falling time are respectively improved by 20 percent.

In one example, the MOS transistor may be adopted in the transistor of the present disclosure. For example, the MOS transistor may he the N-channel transistor.

By adopting the GOA unit described in above, a color shift of the liquid crystal display (LCD) panel can be solved. The color shift indicates the color of the image is different from the original color tone. An additive color mixing model is also referred to as an RGB model, and it is a color information expression method. The additive color mixing model adopts brightness of three primary colors, i.e., red, green, and blue, to quantify the colors, and it is suitable for displays of illuminators. Mixed color shift indicates the color shift in the RGB model display.

By adopting the GOA unit described in above, an x-axis color shift value of the mixed color shift may be reduced by 1 percent and a y-axis of the mixed color shift may be reduced by 4.4 percent. As such, the image-displaying may be more stable, and the display performance may he improved.

In one example, the bootstrap module 6 may include a bootstrap capacitor Cb.

A first end of the bootstrap capacitor Cb connects to the gate signal point. A second end of the bootstrap capacitor Cb connects to the horizontal scanning line G(N). Generally, a capacity of the bootstrap capacitor Cb may be in a range of 15 to 25 pifa. In one example, the bootstrap capacitor Cb may be in a range of 10 to 22 pifa. That is, the appropriate capacitor is adopted to reduce the capacitance. As such, the rising time and the falling time of the potential of the gate signal point Q(N) at the third phase may be further reduced.

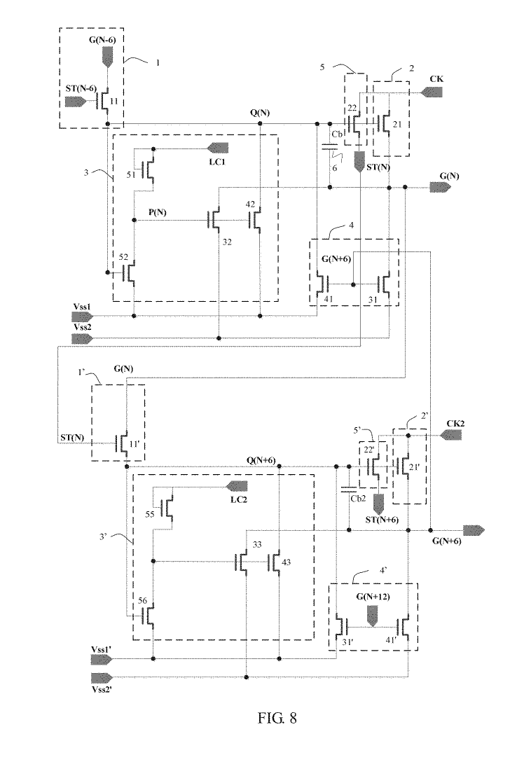

In another aspect, the present disclosure may further relate to a GOA circuit. As shown in FIG. 8, the GOA circuit may include a plurality of the GOA units, described in above, connected in cascade, wherein the GOA unit at the N-th level is configured to control a horizontal scanning line G(N) at the N-th level to conduct a charging process.

The control end of the signal down-transfer circuit in the GOA unit at the N-th level connects to the GOA unit at the next level, wherein “N” is a positive integral.

The GOA unit at the previous level described in above indicates the GOA unit at the previous level connected to the GOA unit at the current level. The GOA unit at the previous level may not be adjacent to the GOA unit at the current level. That is, at least one GOA unit may be physically arranged between the GOA unit at the current level and the GOA unit at the previous level. The GOA unit at the next level described in above indicates the GOA unit at the next level connected to the GOA unit at the current level. The GOA unit at the next level may not be adjacent to the GOA unit at the current level. That is, at least one GOA unit may be physically arranged between the GOA unit at the current level and the GOA unit at the next level. For example, in the structure of the GOA unit at the N-th level and the GOA unit at the (N+6)-th level. The GOA unit at the N-th level may respectively connect to the GOA unit at the previous level, i.e., the GOA unit at the (N−6)-th level, and the GOA unit at the next level, i.e., the GOA unit at the (N+6)-th level.

As shown in FIG: 8, the GOA unit at the current level respectively connects to the GOA unit at the (N−6)-th level and the GOA unit at the next level, i.e., the GOA unit at the (N+6)-th level. The horizontal scanning line G(N) of the GOA unit at N-th level connects an input end of a pull-up controlling module 1′ of the GOA at the (N+6)-th level. The control end of the pull-down circuit of the GOA unit at the N-th level connects to the horizontal scanning line G(N+6) of the GOA at the (N+6)-th level.

The output end of the signal down-transfer circuit of the GOA unit at the N-th level connects to the control end of the pull-up controlling module 1′ of the GOA unit at the (N+6)-th level. Specifically, the signal down-transfer circuit of the GOA unit at the N-th level is configured to output the down-transfer signals ST(N), and is configured to transmit the down-transfer signals ST(N) to the control end of the GOA unit at the (N+6)-th level. The down-transfer signals ST(N) are also referred to as the pull-up controlling signals of the GOA unit at the (N+6)-th level.

It is noted that the GOA unit at the (N−6)-th level may not exist when “N” is less than or equal to “6”. That is, the GOA unit at the N-th level may not connect to the GOA unit at the previous level. The GOA unit at the N-th level is configured to receive the controlling signals or the input signals, and is configured to connect to the GOA unit at the (N+6)-th level.

For example, if “N” is equal to “2”, an output end of a signal down-transfer circuit of a GOA unit at a second level connects to a control end of a pull-up controlling module of a GOA unit at an eighth level. The signal down-transfer circuit of the GOA unit at the second level is configured to output down-transfer signals ST(2), and is configured to transmit the down-transfer signals ST(2) to the control end of the GOA unit at the eighth level. The control end of the pull-up controlling module 1 of the GOA unit at the second level connects an output end of the signal down-transfer circuit of the GOA unit at a first level. A horizontal scanning line G(2) of the GOA unit at the second level connects to an input end of the pull-up controlling module 1′ of the GOA unit at the eighth level. The control end of the pull-down circuit of the GOA unit at the second level connect to a horizontal scanning line G(8) of the GOA unit at the eighth level. The input end of the pull-up controlling module 1 of the GOA unit at the second level connects to a horizontal scanning line G(1) of the GOA unit at the first level.

In another aspect, the present disclosure further relates to a LCD panel, including the GOA unit described in above, and the detail may not be described again. In one example, the LCD panel may be a LCD device. A structure of the LCD is that a liquid crystal cell is arranged between two parallel glass substrates, a thin-film transistor (TFT) is configured on a bottom glass substrate, and a color filter is configured on a top glass substrate. Rotating directions of liquid crystal molecules may be changed by controlling inputted signals and voltages of the TFT. As such, polarized light of each pixel may be outputted.

The person skilled in the art may be aware that the exemplary units and algorithm steps described in the embodiments disclosed herein can be implemented by electronic hardware, computer software, or a combination of the two. In order to clearly illustrate the interchangeability of the hardware with software, the composition and steps of each example have been generally described in terms of functionality in the above description. Whether these functions are implemented in hardware or software depends on the specific application of the technical solution and design constraint conditions. The person skilled in the art may use different methods to implement the described functions for each specific application, but such implementation should not be considered to go beyond the scope of the present disclosure.

In several embodiments provided by the present disclosure, it should be understood that the disclosed apparatus can be implemented in other ways. For example, the device embodiments described above are merely schematic, for example, the division of the units is only one logical function division, and actual implementation may have another division manner, for example, multiple units or components may be combined or may be Integrated into another system, or some features can be ignored or not implemented. In addition, the illustrated or discussed mutual coupling or direct coupling or communication connection may be indirect coupling or communication connection through some interfaces, devices or units, and may be electrical or other forms.

The units described as separate parts may or may not be physically separated, and parts displayed as units may or may not be physical units, that is, may be located in one place, or may be distributed to multiple networks. Some or all of the units may be selected according to actual needs to achieve the purpose of the solution of this embodiment.

In addition, each functional unit in each embodiment of the present disclosure may be integrated in one processing unit, or each unit may exist alone physically, or two or more units may be integrated in one unit. The above integrated unit can be implemented either in hardware or in software.

The present disclosure relates to a GOA unit, a GOA circuit, and a LCD panel. Specific examples are used herein to describe the principle and implementation manner of the present disclosure. The above embodiments are merely used to help to understand the method and the core idea of the present disclosure. For those skilled in the art, the embodiments of the present disclosure may have changes in specific implementation manners and application ranges. In summary, the contents of this specification should not be construed as limiting the present disclosure.

What is claimed is:

1. A gate driver on array GOA) unit, comprising:
a pull-up controlling module, a pull-up circuit, a pull-down maintaining circuit, a pull-down circuit, a signal down-transfer circuit, and a bootstrap module;
an output end of the pull-up controlling module, a control end of the pull-up circuit, a first end of the pull-down maintaining circuit, a first end of the pull-down circuit, a control end of the signal down-transfer circuit, and a first end of the bootstrap module connect to a gate signal point, a second end of the pull-down maintaining circuit, a second end of the pull-down circuit, a second end of the bootstrap module, and an output end of the pull-up circuit connect to a horizontal scanning line, a third end of the pull-down maintaining circuit and a third end of the pull-down circuit connect to a first level signal line, a fourth end of the pull-down maintaining circuit and a fourth end of the pull-down circuit connect to a second level signal line, an input end of the pull-up circuit and the input end of the signal down-transfer circuit connect to a clock signal line, a control end of the pull-down circuit connects to a GOA unit at a next level;
a potential of the first level signal line is lower than a potential of the second level signal line;
the pull-up controlling module is configured to pre-charge the gate signal point, the bootstrap module is configured to store and maintain a level of the gate signal point, when the gate signal point is at a turn-on level, the pull-up circuit is configured to output signals of the clock signal line to the horizontal scanning line;
when control signals received by the control end of the pull-down circuit is configured to be at the turn-on level, the pull-down circuit is configured to output signals of the second level signal line to the horizontal scanning line and to output signals of the first level signal line to the gate signal point, the signals of the first level signal line are configured to control the second end of the pull-down maintaining circuit to output the signals of the second level line to the horizontal scanning line.

2. The GOA unit according to claim 1, wherein the down-pull circuit comprises a first transistor and a second transistor;
a drain of the first transistor connects to the gate signal point, a drain of the second transistor connects to the horizontal scanning line, a source of the first transistor connects to the first level signal line, and a source of the second transistor connects to the second level signals line;
when the gate of the first transistor is at the turn-on level, the source of the first transistor is configured to output the signals of the first level signal line to the drain of the first transistor;
when the gate of the second transistor is at the turn-on level, the source of the second transistor is configured to output the signals of the second level signal line to the drain of the second transistor.

3. The GOA unit according to claim 2, wherein the pull-down maintaining circuit comprises a reverse unit, a fourth transistor, and a fifth transistor;
a control end of the reverse, unit connects to the gate signal point, an output end of the reverse unit connects to a gate of the fourth transistor and a gate of the fifth transistor;
a drain of the fourth transistor connects to the horizontal scanning line, a source of the fourth transistor connects to the second level signal line, a drain of the fifth transistor connects to the gate signal point, and a source of the fifth transistor connects to the first level signal line;
when the control end of the reverse unit is at a low level state, the output end of the reverse unit is configured to output at turn-on level toward the gate of the fourth transistor and the gate of the fifth transistor, the signals of the second level signal line are outputted from the source of the fourth transistor to the drain of the fourth transistor, the signals of the first level signal line are outputted from the source of the fifth transistor to the drain of the fifth transistor.

4. The GOA unit according to claim 3, wherein the reverse unit comprises a sixth transistor and a seventh transistor;
a gate and a drain of the sixth transistor connect to turn-on level signals, a source of the sixth transistor and a drain of the seventh transistor connect to the output end of the reverse unit, and a gate of the seventh transistor connects to the output end of the pull-up controlling module.

5. The GOA unit according to claim 3, wherein a channel width of the first transistor is less than 1000 micron.

6. The GOA unit according to claim 4, wherein the pull-up circuit comprises a third transistor;
a gate of the third transistor connects to the gate signal point, a drain of the third transistor connects to the clock signal line, and a source of the third transistor connects to the horizontal scanning line;
a channel width of the third transistor is greater than 7000 micron;
when the gate f the third transistor is at the turn-on level, the drain of the third transistor is configured to output the signals of the clock signal line to the source of the third transistor.

7. The GOA unit according to claim 5, wherein the potential of the first level signal line is lower than the potential of the second level signal line in a range from 2 to 7 volt.

8. The GOA unit according to claim 7, wherein the bootstrap module comprises a bootstrap capacitor.

9. A GOA circuit comprising:
a plurality of GOA units as claimed in claim 1, the GOA units being connected in cascade, wherein a GOA unit at a N-th level being configured to applying a charging process to a horizontal scanning line at the N-th level;
the control end of the signal down-transfer circuit of the GOA unit at the N-th level connects to the GOA unit at the next level, wherein N is a positive integral.

10. A liquid crystal display (LCD) panel comprises the GOA circuit as claimed in claim 9.
